(19) United States
(12) Patent Application Publication
(10) Pub. No.: US 2023/0317605 A1
(43) Pub. Date: Oct. 5, 2023

(54) INTEGRATED CIRCUITS WITH NARROW WIDTH INTERCONNECTS AND REDUCED RC DELAY

(71) Applicant: Intel Corporation, Santa Clara, CA (US)

(72) Inventors: Abhishek Anil Sharma, Portland, OR (US); Wilfred Gomes, Portland, OR (US); Pushkar Ranade, San Jose, CA (US); Sagar Suthram, Portland, OR (US); Rajabali Koduri, Saratoga, CA (US)

(73) Assignee: Intel Corporation, Santa Clara, CA (US)

(21) Appl. No.: 17/711,917

(22) Filed: Apr. 1, 2022

(51) Int. Cl. H01L 23/528; H01L 27/092; H01L 23/46; H01L 23/522; H01L 23/532; H01L 21/321; H01L 21/3213; H01L 21/768; H01L 21/8238

(52) U.S. Cl. CPC H01L 23/5283; H01L 27/092; H01L 23/46; H01L 23/5226; H01L 23/53228; H01L 23/53242; H01L 23/53257; H01L 23/53276; H01L 21/32115; H01L 21/32133; H01L 21/76892; H01L 21/823871

(57) ABSTRACT

Systems and techniques related to narrow interconnects for integrated circuits. An integrated circuit die includes narrow interconnect lines with a relatively high pitch. A system includes an integrated circuit die with narrow interconnect lines and cooling structure to lower an operating temperature of at least the interconnects to a point where conductance of the narrow interconnect is sufficient.

### BACKGROUND

As integrated circuits operate at higher frequencies and continue to scale, there is an ongoing need for reducing capacitive loads of circuit interconnect wiring as such wiring may contribute to 30%, or more, of power load in any given integrated circuit die. As device densities increase, higher current densities are required and larger conductors generally desired. However, larger, more tightly packed conductors increase interconnect parasitic capacitive load.

It is with respect to these and other considerations that the present improvements have been needed. Such improvements may become critical as the desire to operating frequencies increase even more.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1A illustrates a top view of an example integrated circuit die, including widely spaced parallel interconnect lines, and FIG. 1B illustrates a cross-sectional side view of an example integrated circuit die, including one of a number of widely spaced parallel interconnect lines and an optional adhesive or interface layer, in accordance with some embodiments;

FIGS. 2A, 2B, and 2C illustrate cross-sectional profile views of an integrated circuit die 100, including various examples of interconnect lines 110, in accordance with some embodiments;

FIG. 3 illustrates various processes or methods for forming interconnect lines with narrow line widths on an integrated circuit die, in accordance with some embodiments;

FIGS. 4A, 4B, 4C, 4D, 4E, and 4F illustrate cross-sectional profile views of an integrated circuit die as operations of an exemplary backbone-spacer process flow for manufacturing interconnect lines as practiced, in accordance with some embodiments;

FIG. 5 illustrates various processes or methods for forming interconnect lines with narrow widths on an integrated circuit die, in accordance with some embodiments;

FIGS. 6A, 6B, 6C, 6D, and 6E illustrate cross-sectional profile views of an integrated circuit die as operations of an exemplary process flow using subtractive methods for manufacturing interconnect lines as practiced, in accordance with some embodiments;

FIG. 7 illustrates a cross-sectional view of a low-temperature, integrated circuit system, in accordance with some embodiments;

FIG. 8 illustrates a cross-sectional view of a low-temperature integrated circuit system using die-level, cooling, in accordance with some embodiments;

FIG. 9 illustrates a cross-sectional view of a low-temperature integrated circuit system using package-level cooling, in accordance with some embodiments;

FIG. 10 illustrates a cross-sectional view of a low-temperature integrated circuit system using die-level and package-level cooling, in accordance with some embodiments;

FIG. 11 illustrates a view of an example two-phase immersion cooling system for low-temperature operation of an integrated circuit die, in accordance with some embodiments;

FIG. 12 illustrates a diagram of a data server machine employing integrated circuit dies with narrow interconnect lines, in accordance with some embodiments; and

FIG. 13 is a block diagram of a computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, thermal, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

The vertical orientation is in the z-direction and it is understood that recitations of “top,” “bottom,” “above,” and “below” refer to relative positions in the z-dimension with the usual meaning. However, it is understood that embodiments are not necessarily limited to the orientations or configurations illustrated in the figure.

Integrated circuit dies, systems, and techniques described herein relate to narrow-width interconnects for improved device performance. Metallization (or other interconnect) layers in typical integrated circuit implementations have relatively large interconnect line widths relative to the spaces between the lines, which often limits integrated circuit die performance. Reducing interconnect line widths can enable a space between adjacent interconnect lines to be larger, correspondingly reducing parasitic capacitances between the lines. In accordance with further embodiments, the operating temperature of an integrated circuit die is reduced to below 0° C. and potentially to the cryogenic temperature range so as to greatly increase the conductivity of these narrow line widths and thereby alter the balance between reductions in parasitic capacitance and increases in parasitic line resistance. When integrated with a system configured to sustain very low integrated circuit die operating temperatures, interconnect lines structures heretofore unsuitable become advantageous.

As described further below, integrated circuits have interconnect lines with line-space duty cycles of 50% or lower (e.g., 1%). Line-space duty cycles are calculated as the average width of a conductive line for a sample of adjacent lines divided by the sum of the average width of a conductive line and the average line-to-line pitch for that sample of adjacent lines. In this context, a pitch is the orthogonal distance between a same feature type, e.g., between two lines (e.g., centerline to centerline or top edge to top edge, etc.). In some embodiments, integrated circuits have interconnect line widths less than 10 nm, and potentially 1 nm, or less. In some embodiments, integrated circuits have interconnect lines a single molecular monolayer thick. In some embodiments, integrated circuits have interconnect pitches of no more than 75 nm, and potentially 25 nm, or less. In some embodiments, narrow interconnect lines include an ultra-thin, high-conductivity material.

Methods for forming very narrow interconnect lines with wide pitches are also described herein. For example, spacer-based patterning techniques and monolayer deposition techniques may be practiced in accordance with some embodiments.

Many interconnect materials see a substantial boost in electrical conductivity when operating at very low temperatures. In particular, integrated circuits operating at very low temperatures (e.g., in the cryogenic range) have increased conductivity and reduced surface scattering resistance. In some embodiments, performance of integrated circuits with narrow interconnect lines as described herein is enhanced through their integration with active cooling structures capable of maintaining at least the interconnect lines at very low temperature during the operation of the integrated circuit die. As used herein, the term cooling structure or active cooling structure indicates a device that uses power to provide cooling (e.g., via flow of a coolant, immersion in a coolant, etc.). Notably, the cooling structure or active cooling structure need not be in operation to be labeled as such. The active cooling structures are operable to remove heat from the integrated circuit die to achieve the very lower operating temperature. As used herein, an active cooling structure is a device that uses power to provide cooling (e.g., via flow of a coolant, immersion in a coolant, etc.). The active cooling structure may be part of the integrated circuit die, provided separately from the integrated circuit die, or provisioned in both the integrated circuit die and external to the integrated circuit die. In some contexts, an active cooling structure is not needed as the integrated circuit die is deployed in a very low temperature environment such as in any of a subpolar oceanic climate, a subarctic climate, an arctic climate, a tundra climate, an ice cap climate, or any other environment of sustained cold temperatures.

In some embodiments, the operating temperature of the integrated circuit die is maintained at or below 0° C. In some embodiments, the operating temperature of the integrated circuit die is maintained at or below about −196° C. (i.e., using liquid nitrogen as the coolant). some embodiments, the operating temperature of the IC die is maintained at or below about −25° C. In some embodiments, the operating temperature of the IC die is maintained at or below about −50° C. In some embodiments, the operating temperature of the IC die is maintained at or below about −70° C. In some embodiments, the IC die is maintained at or below about −100° C. Other temperatures may be used based on coolant, environment, and so on.

Reduced electromigration and bidirectional operation, e.g., interconnects within a plane routing in orthogonal directions, are also benefits for interconnects operating in these contexts. Other advantages will be evident based on the following discussion.

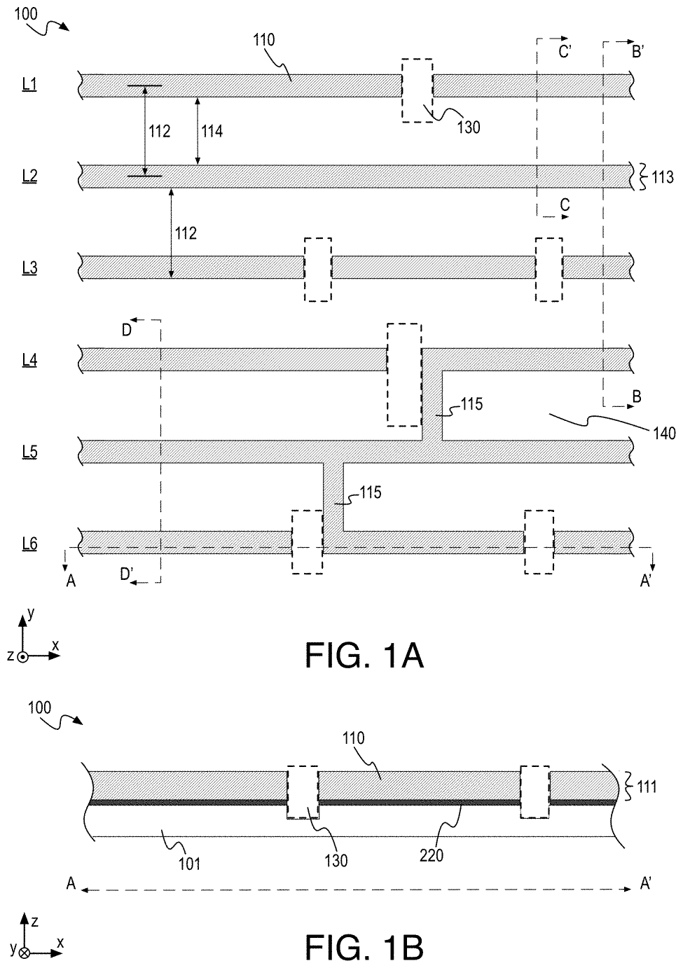

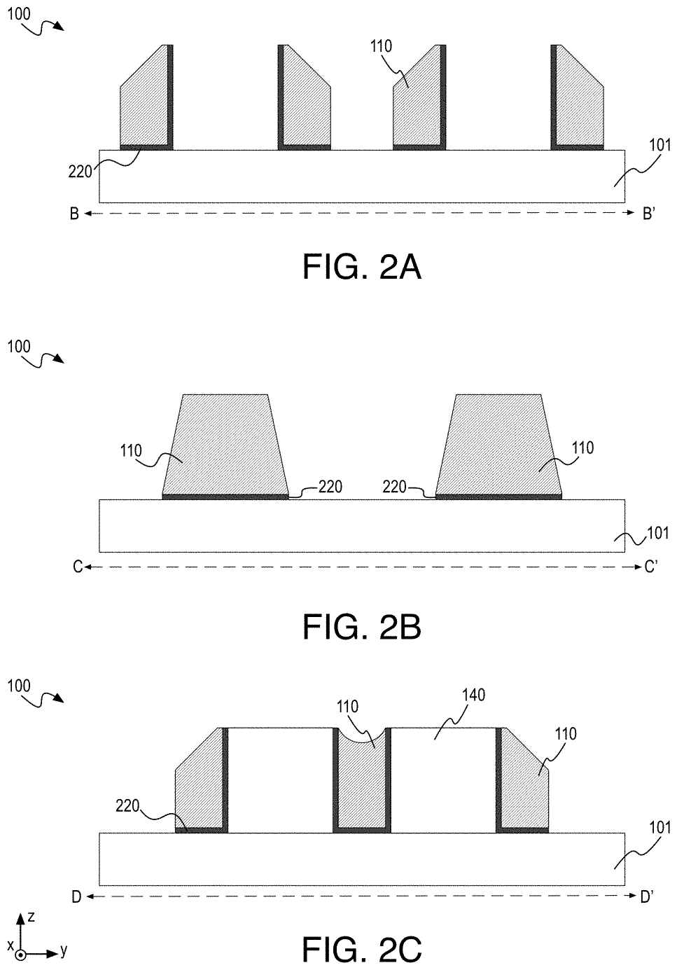

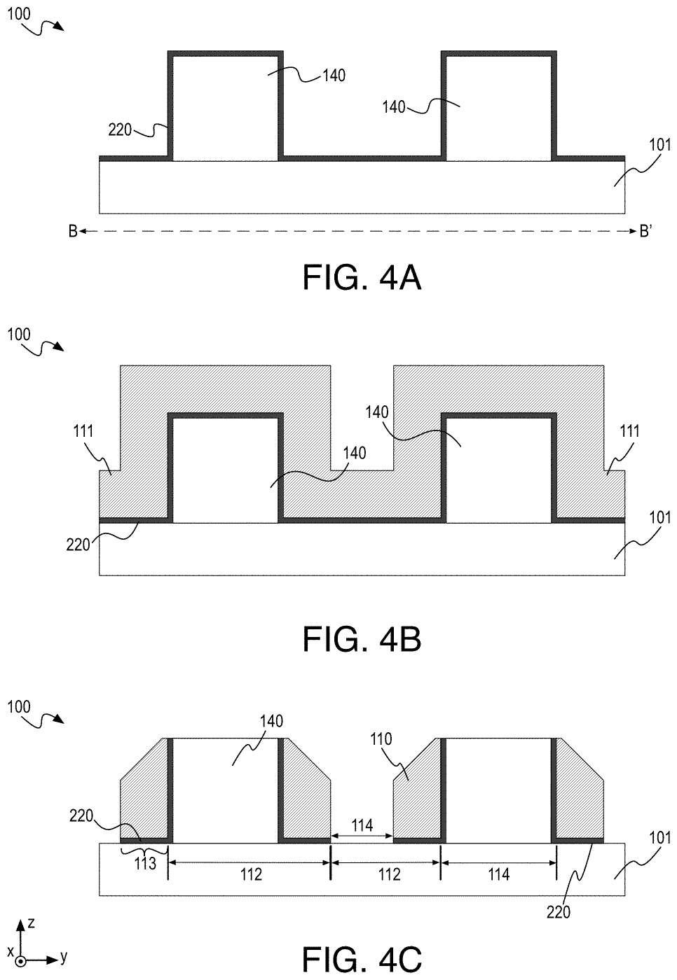

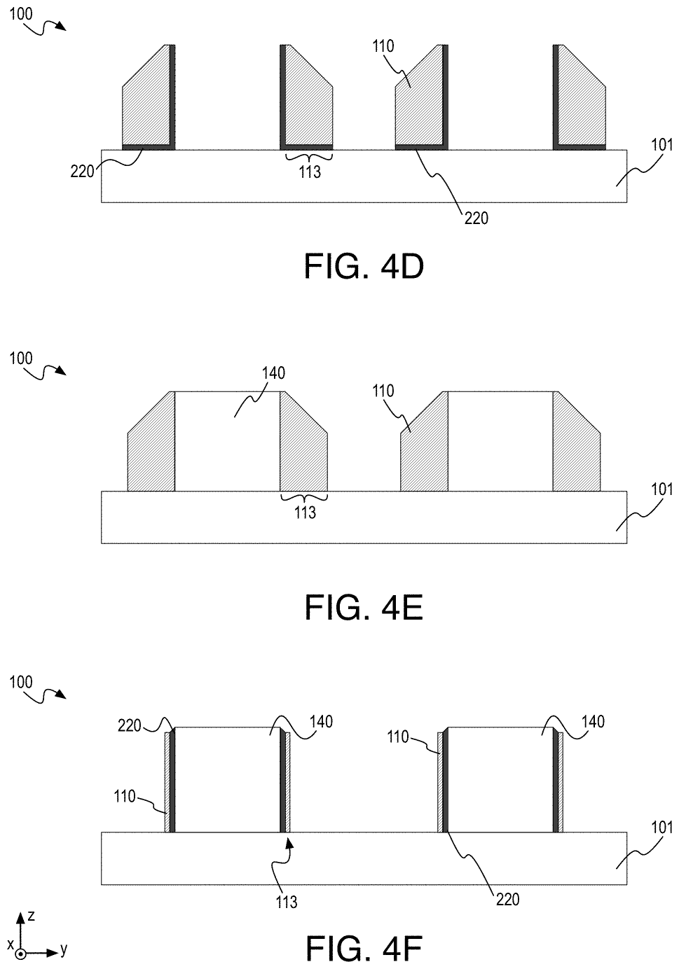

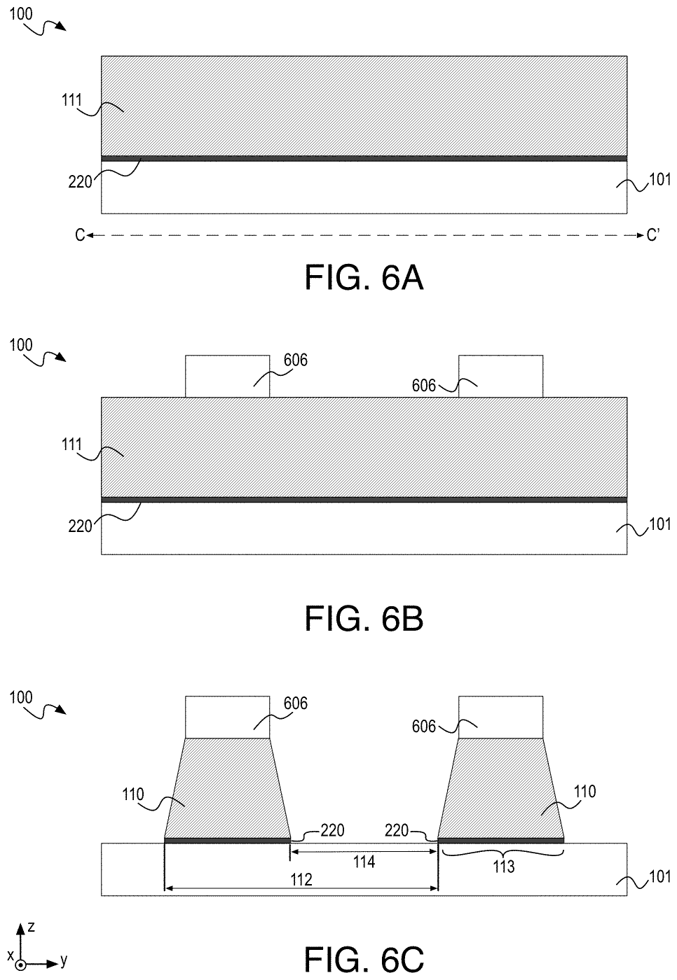

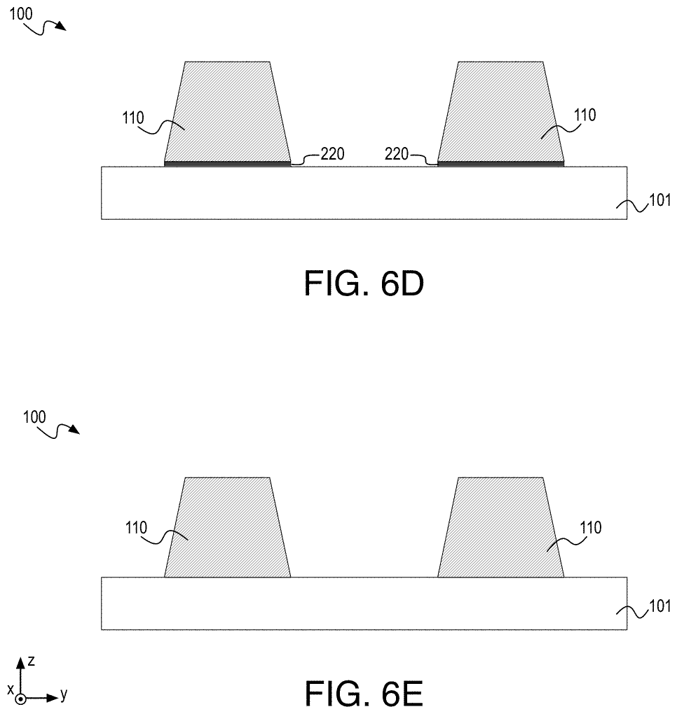

FIG. 1A illustrates a top view of an example integrated circuit die 100, including widely spaced parallel interconnect lines 110, and FIG. 1B illustrates a cross-sectional side view of integrated circuit die 100, including one of a number of widely spaced parallel interconnect lines 110 and an optional adhesive or interface layer 220, in accordance with some embodiments. It is understood that features are shown in FIG. 1 and other figures for illustrative purposes and are not necessarily shown to scale. For example, interconnect lines 110 can be made narrower and farther apart than shown. The example parallel interconnect lines 110 shown in FIG. 1A run generally in the x-direction with small branches 115 in the y-direction connecting to adjacent parallel interconnect lines 110. Interconnect lines 110 have line-to-line pitches 112, line widths 113, and space widths 114. Optional cuts 130 break up interconnect lines 110 where desired. Optionally, spaces between interconnect lines 110 can include (and be set by) backbone features 140 (sometimes referred to as mandrel features). FIG. 1A shows where a cross-sectional side view is taken at A-A′ as shown in FIG. 1B. FIG. 1A also shows where a cross-sectional profile view is taken at B-B′ for FIGS. 2A and 4. FIG. 1A also shows where a cross-sectional profile view is taken at C-C′ for FIGS. 2B and 6. FIG. 1A also shows where a cross-sectional profile view is taken at D-D′ for FIG. 2C.

Pitches 112 are measured from centerline to centerline, or lower edge to lower edge, etc., and include the line widths 113 and space widths 114. These widths (whether 113 of the lines or 114 of the spaces between them) are taken orthogonally to the lengths of interconnect lines 110. Space widths 114 are taken between nearest ones of interconnect lines 110. Some of these dimensions may vary somewhat along a line length, e.g., along the x-dimension in FIG. 1A, but representative samples can be taken and averaged to obtain representative widths of lines and spaces. Together, these dimensions are used to define a “line-space duty cycle” of a set of parallel interconnect lines 110 as the sum of the line widths 113 divided by the sum of the pitches 112. As one pitch 112 is equal to one line width 113 plus one space width 114, a line-space duty cycle can also be calculated as the sum of line widths 113 divided by the sum of line widths 113 plus space widths 114. For a set of n interconnect lines 110, there will be n line widths 113 and n−1 space widths 114. The line-space duty cycle can be calculated as the sum of n−1 line widths 113 (the line widths 113 of either the first through the n−1^{th} or the second through the n^{th} interconnect lines 110, i.e., all but one of the end interconnect lines 110 of the set) divided by the sum of the same n−1 line widths 113 and the n−1 space widths 114 between the n interconnect lines 110. For example, in FIG. 1A, the six (n=6) parallel interconnect lines 110 are labeled L1 (at top) through L6 (at bottom) and can be assigned respective line widths 113 of LW₁ through LW₆. For example, L2, as shown in FIG. 1A as the line width labeled 113, corresponds to LW₂. There are five (i.e., n−1=5) intervening spaces between the six interconnect lines 110, which can be assigned space widths 114 of SW₁₂, SW₂₃, SW₃₄, SW₄₅, and SW₅₆, where the two-digit designator indicates the two lines on either side of the indicated space width 114, e.g., SW₁₂ is between L1 and L2 and, as shown in FIG. 1A, is the space width labeled 114. In the example, the line-space duty cycle can be calculated as the sum of five consecutive line widths 113, e.g., LW₁ through LW₅, divided by the sum of both those line widths 113 and the five intervening space widths 114, i.e., SW₁₂, SW₂₃, SW₃₄, SW₄₅, and SW₅₆. The calculation could alternately use LW₂ through LW₆, in place of LW₁ through LW₅ in both the numerator and divisor of the calculation. The same five consecutive line widths 113 should be used in both sums.

Small line-space duty cycles correspond to small line widths 113 of interconnect lines 110 and large space widths 114 between interconnect lines 110, which translate to smaller capacitances between adjacent interconnect lines 110. Smaller capacitances between adjacent interconnect lines 110 are generally beneficial, but particularly when adjacent interconnect lines 110 are, e.g., high-speed signal lines. Small widths of interconnect lines 110 also correspond to less metal used. In some embodiments, interconnect lines 110 are formed with line-space duty cycles of 50%. Although a smaller cross-sectional width of interconnect lines 110 increases their electrical resistance, the low system temperature can reduce such a resistance penalty through a material conductivity improvement. In some embodiments, the techniques employed to form narrow line widths is conducive to the use of highly conductive materials. Hence, some embodiments wherein interconnect lines 110 have a line-space duty cycle of 1%, or even 0.5%, may nevertheless display sufficiently high conductance at the low operating temperature of the integrated circuit.

A number of various high-conductivity materials may be beneficial when forming narrow interconnect lines 110. In some embodiments, interconnect lines 110 include ruthenium or tungsten. In some embodiments, interconnect lines 110 include ultrathin, highly conductive materials, e.g., two-dimensional (2D) materials. In some embodiments, interconnect lines 110 include a metal chalcogenide, such as a transition-metal dichalcogenide (TMD) that includes one or more metal and one or more of sulfur, selenium, or tellurium. In some embodiments, interconnect lines 110 include copper and sulfur, copper and selenium, or copper and tellurium. In some embodiments, interconnect lines 110 include graphene, which is another example of a 2D material. For any of the 2D material embodiments, interconnect lines 110 may include as little as a single molecular monolayer of such highly conductive materials.

Any suitable methods can be used to form narrow-width interconnect lines 110. For example, damascene processes can be used to form interconnect lines 110 of copper. Subtractive methods may be particularly useful for narrowing the interconnect lines 110. In some embodiments described further below, backbone-spacer processes are used to form narrow interconnect lines 110 and to easily control line pitch 112.

In backbone-spacer processes, spacers may be formed around pre-patterned features used as backbones. A conductive material can be formed, e.g., deposited via chemical vapor deposition (CVD), over backbone features 140 and then undesired portions of the conductive material can be removed, leaving only interconnect lines 110 as loops around backbone features 140. The loops can then be cut where desired to leave the separated spacers as interconnect lines 110, electrically isolated where desired by cuts 130. In some embodiments, backbone features 140 are placed closely together such that the loops around adjacent backbone features 140 are joined. In some embodiments, branches 115 are formed by these joinings. In some embodiments, backbone features 140 are placed apart such that the loops around backbone features 140 are not joined and the pitches 112 between eventual interconnect lines 110 are large.

Besides branches 115, other, longer interconnect lines 110 may run in the y-direction, i.e., orthogonally to the parallel interconnect lines 110 shown generally in the x-direction. In some embodiments, backbone features 140 are patterned with longer lengths in the y-direction and result in interconnect lines 110 running generally in the y-direction. In some embodiments, other processes are used to form interconnect lines 110 running generally in the y-direction.

FIG. 1B illustrates a cross-sectional side view of an example integrated circuit die 100, including one of a number of widely spaced parallel interconnect lines 110 and an optional adhesive or interface layer 220, arranged in accordance with at least some implementations of the present disclosure. FIG. 1B provides a cross-sectional side view at A-A′ as shown in FIG. 1A. Interconnect line 110 is formed from a layer of a conductive material 111. Optional interface layer 220 is between interconnect line 110 and substrate 101. Optional cuts 130 extend through interconnect line 110 and interface layer 220, all the way into substrate 101, to break up interconnect line 110 where desired, e.g., to electrically isolate parallel interconnect lines 110 that were formed as parts of a contiguous loop around backbone features 140 (as shown in FIG. 1A). Cuts 130 may also be used to break up interconnect lines 110 beyond where other features are connected, e.g., beyond where interconnect line 110 meets a via (not shown) connecting interconnect line 110 to another interconnect line 110 on a layer above or below the layer shown.

Adhesive or interface layer 220 is optional, but can be used to help adhere conductive material 111 on substrate 101. Adhesive or interface layer 220 can be useful when the desired line widths of interconnect lines 110 are very small, particularly if excess conductive material 111 is to be removed, e.g., by subtractive methods described below. Adhesive or interface layer 220 can also be useful depending on the various chemical compositions of substrate 101 and conductive material 111. In some embodiments, interface layer 220 includes a precursor material for forming interconnect lines 110. In some embodiments, interface layer 220 includes an electrically conductive material. In some embodiments, interface layer 220 includes an electrically insulative material. In some embodiments, interface layer 220 includes tantalum or titanium. In some embodiments, interface layer 220 includes tantalum nitride.

Substrate 101 may be one of many layers in integrated circuit die 100. Substrate 101 may be an upper layer in integrated circuit die 100. Substrate 101 may be a lower layer in integrated circuit die 100. Integrated circuit die 100 may have layers above and below substrate 101. As will be illustrated below, integrated circuit die 100 may have a number of transistors and one or more dielectric layers above or below the transistors. In some embodiments, integrated circuit die 100 has transistors connected to electrical vias that interconnect lines 110 will connect to.

FIGS. 2A, 2B, and 2C illustrate cross-sectional profile views of an integrated circuit die 100, including various examples of interconnect lines 110, in accordance with some embodiments. For example, FIGS. 2A, 2B, and 2C provide cross-sectional profile views at B-B′, C-C′, and D-D′ as shown in FIG. 1A.

FIG. 2A shows integrated circuit die 100 with four parallel interconnect lines 110 running over substrate 101 in the x-direction. Interconnect lines 110 were formed using a backbone-spacer process. As will be described in more detail below, the trapezoidal profiles are indicative of the subtractive process used in removing, e.g., some of a conductive material and optional interface layer 220. In this case, undesired backbone features 140 have been optionally removed from substrate 101. The asymmetric (but pair-symmetric) profiles are indicative of the backbone-patterning process used in forming interconnect lines 110. FIG. 2B shows integrated circuit die 100 with two parallel interconnect lines 110 running over substrate 101 in the x-direction. Subtractive methods were used in forming interconnect lines 110. As will be described in more detail below, the trapezoidal profiles are evidence of the subtractive process used in removing, e.g., some of a conductive material and optional interface layer 220. Although subtractive processes are often indicated by trapezoidal profiles, in some embodiments, the cross-sectional profiles of interconnect lines 110 are substantially rectangular.

FIG. 2C shows integrated circuit die 100 with three parallel interconnect lines 110 running over substrate 101 in the x-direction. Interconnect lines 110 were formed using a backbone-spacer process. The trapezoidal profiles seen on the outer interconnect lines 110 are indicative of the subtractive process used in removing, e.g., some of a conductive material and optional interface layer 220. In this case, backbone features 140 have been optionally retained on substrate 101. The asymmetric (but pair-symmetric) profiles, this time of the outer interconnect lines 110, are indicative of the backbone-patterning process used in forming interconnect lines 110. In this embodiment, adjacent backbone features 140 are spaced sufficiently close such that the center interconnect line 110 was formed between adjacent pairs of backbone features 140. The closely spaced adjacent backbone features 140 did not leave center interconnect line 110 as exposed to the subtractive method used, e.g., an etch, so center interconnect line 110 had less conductive material removed than outer interconnect lines 110.

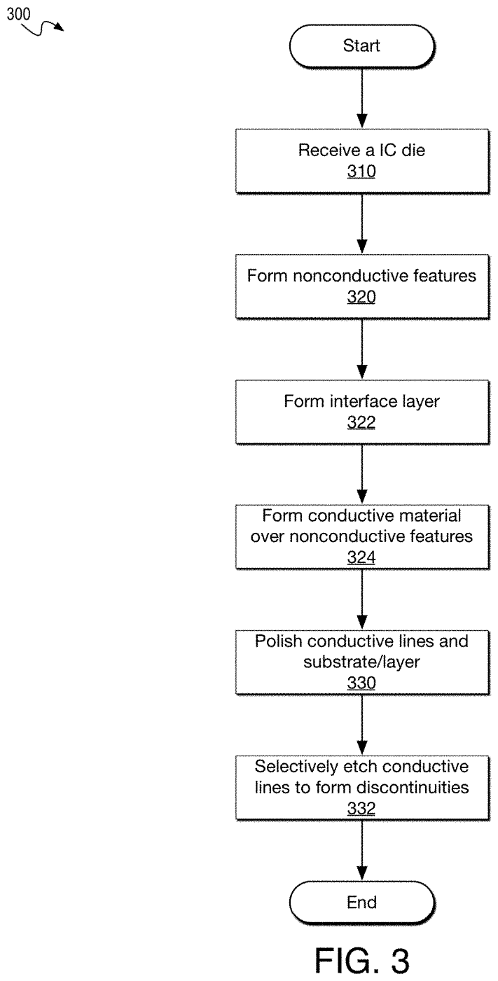

FIG. 3 illustrates various processes or methods 300 for forming interconnect lines with narrow line widths on an integrated circuit die, in accordance with at least some implementations of the present disclosure. The processes include receiving an integrated circuit die and various methods of forming interconnect lines and of removing portions of the interconnect lines. FIG. 3 shows operations using a backbone-spacer process. Operations 320, 322, and 324 can be performed to form interconnect lines on a substrate, such as a dielectric layer, of an integrated circuit die. Operations 330 and 332 can be performed to remove portions of the interconnect lines as necessary or desired.

As shown in FIG. 3, an integrated circuit die is received in operation 310. In some embodiments, the integrated circuit die is received as part of a wafer also having many other integrated circuit dies.

In operation 320, features can be patterned on an upper surface of a substrate, e.g., a dielectric layer. The features can be thought of as backbone features as subsequent materials will be formed over these pre-patterned features. In some embodiments, the backbone features include nonconductive materials. In some embodiments, the backbone features include oxygen, such as an oxide material. In some embodiments, the backbone features include nitrogen, such as a nitride material. Interconnect lines will be formed from the subsequent materials to be formed over the backbone features, so the sizes, shapes, and locations of the backbone features will influence the layout of the eventual interconnect lines to be formed. Wide backbone features will result in interconnect lines with correspondingly wide line-to-line pitches. In some embodiments, backbone features are patterned with wide enough dimensions to yield line-space duty cycles of 5%. In some embodiments, pitches are 75 nm. Tall backbone features can result in interconnect lines with correspondingly tall sidewalls facing those backbone features. Backbone features patterned relatively far from other backbone features will result in interconnect lines spaced correspondingly far from each other, i.e., at a relatively wide pitch. In some embodiments, wide backbone features are patterned far enough from other wide backbone features to yield line-space duty cycles of 1%. In some embodiments, pitches are 50 nm.

In operation 322, an interface layer can be formed on, e.g., deposited over, the backbone features and the substrate. Forming an adhesive or interface layer is not a required operation, but may be beneficial in some embodiments, e.g., with certain material combinations, and especially with lower interconnect line widths and when using subtractive process methods.

In operation 324, a layer (or multiple layers) of conductive material can be formed on, e.g., deposited over, the backbone features and the substrate or, optionally, an interface layer formed on the backbone features and the substrate. In some embodiments, the layer(s) of conductive material are ultrathin. In some embodiments, the layer(s) of conductive material are less wide than 1 nm. In some embodiments, the layer(s) of conductive material are formed from the backbone features. In some embodiments, the layer of conductive material is a monolayer of graphene formed from an outer layer of a backbone feature of amorphous carbon, e.g., by a surface anneal operation. In some embodiments, the layer of conductive material includes ultrathin, highly conductive materials, e.g., a 2D metal chalcogenide, such as a TMD. In some embodiments, the layer of conductive material is a monolayer of TMD formed from an interface layer of a precursor metal on a backbone feature, e.g., by a reaction of that precursor metal with a precursor chalcogen gas. In some embodiments, the layer of conductive material includes tungsten or copper. In some embodiments, the layer of tungsten or copper is reacted with sulfur, selenium, or tellurium to form a layer of conductive material including tungsten or copper, and one or more of sulfur, selenium, or tellurium.

In operation 330, excess material is removed from the formed interconnect lines by polishing. Until excess material is removed, the formed interconnect lines may be part of one or more uninterrupted layers of conductive material. Anisotropic etch and/or polishing can be used to remove excess conductive material from above and adjacent to the backbone features beyond a width of the spacer of conductive material that is retained. In some embodiments, when an interface layer is used, excess material is removed from the interface layer, e.g., by polishing, before a conductive material is formed on the interface layer.

Pitches can be further increased, and line-space duty cycles decreased, by narrowing interconnect lines by removing excess conductive material. In some embodiments, interconnect lines are narrowed enough to yield line-space duty cycles of 5%. Pitches can be further increased, and line-space duty cycles decreased, by removing (e.g., by isotropic etching) one of the spacers formed on either side of a backbone. Such an etch process may be performed after selective removal of the backbone, for example. In some embodiments, removing half of a backbone's spacers yields line-space duty cycles of 0.5%.

In operation 332, undesired conductive material is removed by selectively etching gaps in the interconnect lines. Although excess conductive material may have been removed from above and between the backbone features, the conductive material may still form contiguous loops around the perimeters of the backbone features. These loops can be cut into electrically isolated interconnect lines by etching gaps in the loops of conducting material. In some embodiments, these discontinuities are formed using a cut mask to selectively etch across the interconnect lines.

FIGS. 4A, 4B, 4C, 4D, 4E, and 4F illustrate cross-sectional profile views of an integrated circuit die 100 as operations of an exemplary backbone-spacer process flow for manufacturing interconnect lines 110 as practiced, in accordance with some embodiments. For example, FIGS. 4A, 4B, 4C, 4D, 4E, and 4F provide cross-sectional profile views at B-B′ as shown in FIG. 1A. As shown in FIG. 4, four parallel interconnect lines 110 are formed as spacers by depositing conductive material 111 over optional adhesive or interface layer 220, which is first deposited over pre-patterned backbone features 140 on substrate 101. Extra conductive material 111 is removed, as is adhesive or interface layer 220, to leave separate interconnect lines 110 as spacers on both sides of backbone features 140. Backbone features 140 can remain between adjacent pairs of interconnect lines 110 or can optionally be removed.

FIG. 4A shows integrated circuit die 100 after backbone features 140 have been patterned onto substrate 101 and optional adhesive or interface layer 220 has been deposited over backbone features 140. Substrate 101 may be one of many layers in integrated circuit die 100. Substrate 101 may be above other layers in integrated circuit die 100, layers with transistors and/or layers with other interconnect lines 110. In some embodiments, multiple layers with interconnect lines 110 are used to electrically connect transistors or other components in lower layers of integrated circuit die 100 to connections at the top of integrated circuit die 100 to one or more power supplies or other integrated circuit dies 100. Substrate 101 may be below other layers in integrated circuit die 100, layers with transistors and/or layers with other interconnect lines 110. In some embodiments, multiple layers with interconnect lines 110 are used to electrically connect transistors or other components in other layers of integrated circuit die 100 to connections at the bottom of integrated circuit die 100 to one or more power supplies or other integrated circuit dies 100. Although other layers are sometimes referred to as being, e.g., lower, or above or below another layer, a “lower” layer in one orientation can be an “upper” layer by reversing the orientation. For example, many operations that can be performed on a substrate's surface can also be performed on an opposite surface of the same substrate.

Backbone features 140 can be patterned such that the line-space duty cycle of interconnect lines 110 will be large. Where adjacent backbone features 140 are spaced sufficiently, pairs of interconnect lines 110 will be formed with one interconnect line 110 on either side of each backbone feature 140, so backbone features 140 can be patterned to make large spaces between interconnect lines 110. Where adjacent backbone features 140 are spaced sufficiently close, a single interconnect line 110 will be formed between adjacent pairs of backbone features 140. Backbone features 140 can be patterned and formed from any suitable material. In some embodiments, backbone features 140 are formed from a dielectric material. In some embodiments, backbone features 140 are formed from amorphous carbon.

Adhesive or interface layer 220 is optional, but can be used, as in the example shown in FIG. 4A, to help adhere conductive material 111 subsequently deposited on substrate 101. Adhesive or interface layer 220 can be useful when the desired widths of eventual interconnect lines 110 will be very small, particularly if excess conductive material 111 will subsequently be removed. Adhesive or interface layer 220 can also be useful depending on the various materials used, e.g., for substrate 101 and conductive material 111 for eventual interconnect lines 110. In some embodiments, interface layer 220 includes a precursor material for forming interconnect lines 110. In some embodiments, interface layer 220 includes an electrically conductive material. In some embodiments, interface layer 220 includes an electrically insulative material. In some embodiments, interface layer 220 includes a dielectric material. In some embodiments, interface layer 220 includes tantalum or titanium. In some embodiments, interface layer 220 includes tantalum nitride. In some embodiments, interface layer 220 includes titanium.

FIG. 4B shows integrated circuit die 100 after conductive material 111 has been deposited over interface layer 220, which covers backbone features 140 and substrate 101. Conductive material 111 can be chosen to form interconnect lines 110 for any of a number of reasons, e.g., for high conductivity to facilitate low line-space duty cycles. In some embodiments, conductive material 111 includes copper. In some embodiments, conductive material 111 includes ultrathin, highly conductive materials, e.g., 2D metals. In some embodiments, conductive material 111 includes TMDs. In some embodiments, conductive material 111 includes ruthenium or tungsten. In some embodiments, conductive material 111 includes sulfur, selenium, or tellurium. In some embodiments, conductive material 111 includes one or more metals and one or more of sulfur, selenium, or tellurium. In some embodiments, conductive material 111 includes copper and sulfur, copper and selenium, or copper and tellurium. In some embodiments, conductive material 111 includes graphene.

The thickness of conductive material 111 deposited over backbone features 140 and substrate 101 (and optional interface layer 220) sets the maximum width and thickness of eventual interconnect lines 110. Subtractive patterning methods can further reduce the size, e.g., cross-sectional width, of the layer of conductive material 111 and eventual line width 113 of interconnect lines 110 to less than this upper bound.

FIG. 4C shows integrated circuit die 100 after excess conductive material 111 and interface layer 220 have been removed, leaving apparent pairs of interconnect lines 110. In some embodiments, excess conductive material 111 and interface layer 220 are removed by an anisotropic etch process. Subtractive processes can remove conductive material 111 and interface layer 220 from above and between backbone features 140, while retaining a thickness of conductive material 111 immediately adjacent to a sidewall of backbone features 140. The eventual line width 113 can be reduced to less than the initial width of conductive material 111 formed on interface layer 220 on backbone features 140. The apparent pairs of interconnect lines 110 may remain electrically connected to each other, as they may still be in continuous loops around their respective backbone features 140 until cuts are made through interconnect lines 110 where desired and, if necessary, e.g., to electrically isolate certain interconnect features from other interconnect features.

The subtractive process used is evidenced by the generally trapezoidal profiles of the remaining structures. The widths at the tops of interconnect lines 110 are narrower than the widths at the bottoms of interconnect lines 110. Although the profiles in FIG. 4C (and later) are illustrated and described as trapezoidal, the various sides, tops, etc., of the resultant structures may not actually be completely planar or meet at abrupt edges or corners. These faces and intersections may be at least slightly curved or rounded. Substantially rectangular profiles are also possible with some subtractive processes. In some embodiments, the cross-sectional profiles of interconnect lines 110 are substantially rectangular.

The backbone-spacer process is evidenced by the asymmetric profiles of interconnect lines 110. Although interconnect lines 110 are not symmetric, adjacent pairs of interconnect lines 110 are symmetric about a centerline through the space between the adjacent pair of interconnect lines. As illustrated, interconnect lines 110 have taller sidewalls facing in (towards the respective backbone feature 140 and the paired interconnect line 110), and shorter sidewalls facing out (away from the respective backbone feature 140 and the paired interconnect line 110).

Line-to-line pitches 112 and space widths 114 depend on distances between adjacent interconnect lines 110, whether they are paired or not. Line-to-line pitches 112 and space widths 114 vary with the widths of, as well as the distances between, backbone features 140. As interconnect lines 110 are paired by backbone features 140, it can be seen that wider backbone features 140 lead to wider pairs of interconnect lines 110 and space widths 114 or larger pitches 112 from one interconnect line 110 to the next and smaller line-space duty cycles. In some embodiments, interconnect lines 110 are formed with line-space duty cycles of 10%. In some embodiments, backbone features 140 are yet wider and interconnect lines 110 are formed with line-space duty cycles of 1%. In some embodiments, backbone features 140 are formed of amorphous carbon and interconnect lines 110 are monolayers of graphene formed on the amorphous carbon backbone features 140. In some embodiments, interconnect lines 110 are monolayers of TMD formed by reacting a surface thickness of backbone features 140 comprising a precursor metal.

FIG. 4D shows integrated circuit die 100 after undesired backbone features 140 have been optionally removed from substrate 101. Interconnect lines 110 have thin line widths 113. Again, the trapezoidal profiles are evidence of the subtractive process used earlier in removing some of, e.g., conductive material 111 and optional adhesive or interface layer 220. The asymmetric (but pair-symmetric) profiles are indicative of the backbone-patterning process used in forming interconnect lines 110. In some embodiments, backbone features 140 are kept. In some embodiments, backbone features 140 are removed.

FIG. 4E shows a similar example integrated circuit die 100 and interconnect lines 110 with narrow line widths 113, but with backbone features 140 optionally retained without optional interface layer 220. In some embodiments, no interface layer 220 is used and backbone features 140 are kept. In some embodiments, no interface layer 220 is used and backbone features 140 are removed. In some embodiments, interface layer 220 is used and backbone features 140 are kept. In some embodiments, interface layer 220 is used and backbone features 140 are removed.

FIG. 4F shows a similar example integrated circuit die 100 and interconnect lines 110, with backbone features 140 optionally left on substrate 101, but with ultrathin interconnect lines 110 formed on adhesive or interface layer 220. Interconnect lines 110 have thin line widths 113 with dimensions similar to those of adhesive or interface layer 220. In some embodiments, excess portions of interface layer 220 are removed from above and between backbone features 140 before interconnect lines 110 are formed (from conductive material 111) on adhesive or interface layer 220. In some embodiments, interface layer 220 is a seed layer for forming interconnect lines 110 by depositing conductive material 111. In some embodiments, interconnect lines 110 are formed from a precursor or interface layer 220 over backbone features 140. In some embodiments, interconnect lines 110 of graphene are formed, e.g., by a surface anneal operation, from a precursor or interface layer 220 comprising carbon. In some embodiments, interconnect lines 110 of TMD are formed from an interface layer 220 of a precursor metal on a backbone feature 140, e.g., by a reaction with a precursor chalcogen gas.

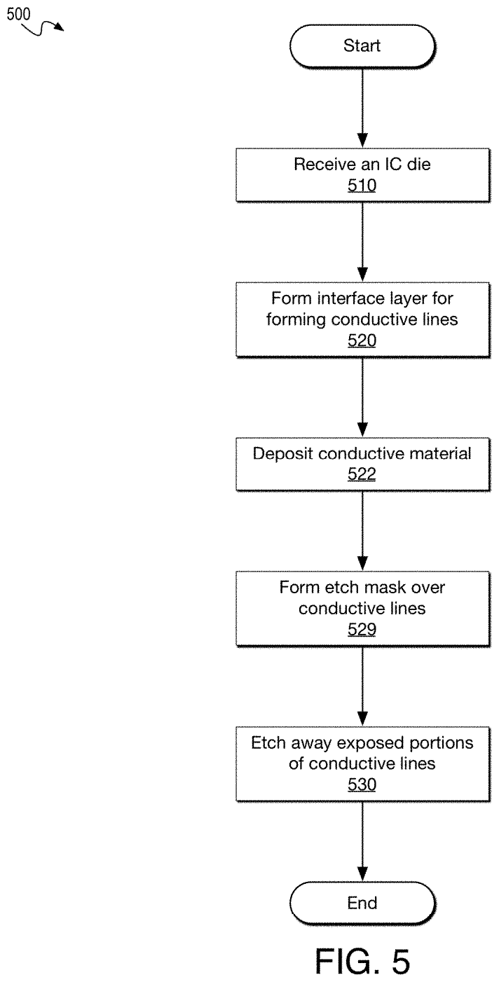

FIG. 5 illustrates various processes or methods 500 for forming interconnect lines with narrow widths on an integrated circuit die, arranged in accordance with at least some implementations of the present disclosure. The processes include receiving an integrated circuit die and various methods of forming interconnect lines and of removing portions of the interconnect lines. FIG. 5 shows operations using a subtractive process. Operations 520 and 522 can be performed to form the conductive material for the interconnect lines on a substrate on an integrated circuit die, such as a dielectric layer. Operations 529 can be performed to prepare for removal of portions of the interconnect lines and helps determine the eventual size, shape, and layout of the interconnect lines. Operation 530 can be performed to remove portions of the interconnect lines as necessary or desired.

As shown in FIG. 5, an integrated circuit die is received in operation 510. In some embodiments, the integrated circuit die is received as part of a wafer also having many other integrated circuit dies

In operation 520, an interface layer can be formed on, e.g., deposited over, the substrate. Forming an adhesive or interface layer is not a required operation, but may be beneficial in some embodiments, particularly for this subtractive process and, e.g., with certain material combinations and especially with lower interconnect line widths.

In operation 522, a layer (or multiple layers) of conductive material can be formed on, e.g., deposited over, the substrate or, optionally, an interface layer formed on the substrate. In some embodiments, the layer(s) of conductive material can be ultrathin. In some embodiments, the layer of conductive material is a monolayer of graphene formed from amorphous carbon, e.g., by a surface anneal operation. In some embodiments, the layer(s) of conductive material include ultrathin, highly conductive materials, e.g., 2D metals, such as TMDs. In some embodiments, the layer(s) of conductive material are TMD formed from a precursor metal, e.g., by a reaction with a precursor chalcogen gas. In some embodiments, the layer(s) of conductive material include ruthenium or tungsten. In some embodiments, the layer(s) of conductive material include sulfur, selenium, or tellurium. In some embodiments, the layer(s) of conductive material include one or more metals, such as copper, and one or more of sulfur, selenium, or tellurium.

In operation 529, an etch mask can be formed, e.g., by patterning photoresist, over those portions of the conductive material meant to remain on the substrate as interconnect lines.

In operation 530, undesired conductive material is removed by selectively etching away undesired conductive material, i.e., by removing conductive material not covered by photoresist, to form the interconnect lines from the remaining conductive material.

FIGS. 6A, 6B, 6C, 6D, and 6E illustrate cross-sectional profile views of an integrated circuit die 100 as operations of an exemplary process flow using subtractive methods for manufacturing interconnect lines 110 as practiced, in accordance with some embodiments. For example, FIG. 6 provides cross-sectional profile views at C-C′ as shown in FIG. 1A. As shown in FIG. 6, two parallel interconnect lines 110 are formed by depositing conductive material 111 over optional adhesive or interface layer 220, which is first deposited over substrate 101. Extra conductive material 111 is removed, as is adhesive or interface layer 220, to leave separate interconnect lines 110 on substrate 101.

FIG. 6A shows integrated circuit die 100 after optional adhesive or interface layer 220 and conductive material 111 have both been deposited over substrate 101. Substrate 101 may be one of many layers in integrated circuit die 100. Substrate 101 may be above other layers in integrated circuit die 100, layers with transistors and/or layers with other interconnect lines 110. In some embodiments, multiple layers with interconnect lines 110 are used to electrically connect transistors or other components in lower layers of integrated circuit die 100 to connections at the top of integrated circuit die 100 to one or more power supplies or other integrated circuit dies 100. Substrate 101 may be below other layers in integrated circuit die 100, layers with transistors and/or layers with other interconnect lines 110. In some embodiments, multiple layers with interconnect lines 110 are used to electrically connect transistors or other components in other layers of integrated circuit die 100 to connections at the bottom of integrated circuit die 100 to one or more power supplies or other integrated circuit dies 100.

As discussed above, adhesive or interface layer 220 is optional, but can be used, as in the example shown in FIG. 6A, to help adhere conductive material 111 on substrate 101. At least some materials described in contexts above, e.g., the process shown in FIG. 4, can be used similarly in FIG. 6.

Conductive material 111 can be chosen to form interconnect lines 110 for any of a number of reasons, e.g., for high conductivity to facilitate low line-space duty cycles. In some embodiments, conductive material 111 includes copper. In some embodiments, conductive material 111 includes ultrathin, highly conductive materials, e.g., 2D metals. In some embodiments, conductive material 111 includes TMDs. In some embodiments, conductive material 111 includes ruthenium or tungsten. In some embodiments, conductive material 111 includes sulfur, selenium, or tellurium. In some embodiments, conductive material 111 includes one or more metals and one or more of sulfur, selenium, or tellurium. In some embodiments, conductive material 111 includes copper and sulfur, copper and selenium, or copper and tellurium. In some embodiments, conductive material 111 includes graphene.

FIG. 6B shows integrated circuit die 100 after an etch mask 606 has been formed on conductive material 111. Etch mask 606 can be formed on conductive material 111 wherever eventual interconnect lines 110 are meant to remain from the layer of conductive material 111. In some embodiments, etch mask 606 is formed as a photoresist.

FIG. 6C shows integrated circuit die 100 after excess conductive material 111 and interface layer 220 have been removed by an anisotropic etch, leaving interconnect lines 110 (under etch mask 606 and over interface layer 220) on substrate 101. The subtractive process used is evident from the trapezoidal profiles of the remaining structures. The widths at the tops of interconnect lines 110 are narrower than line widths 113 at the bottoms of interconnect lines 110. Line widths 113 are determined by etch mask 606 and various etch process parameters.

The layout of interconnect lines 110 is determined in part by etch mask 606, which can be used to narrow the line widths 113 of interconnect lines 110 or widen pitches 112 and space widths 114, and so lower the line-space duty cycles. In some embodiments, interconnect lines 110 are formed with line-space duty cycles of 10%. In some embodiments, interconnect lines 110 are formed with line-space duty cycles of 0.5%.

FIG. 6D shows integrated circuit die 100 with interconnect lines 110 after etch mask 606 has been optionally removed from substrate 101. Again, the trapezoidal profiles are indicative of the subtractive process used earlier in removing some of, e.g., conductive material 111 and optional interface layer 220.

FIG. 6E shows a similar example integrated circuit die 100 and interconnect lines 110, but as if the process described in FIGS. 6A, 6B, 6C, and 6D had been performed without optional interface layer 220. In some embodiments, no interface layer 220 is used, and, as described in FIG. 6A, conductive material 111 is formed directly on substrate 101. In some embodiments, as described in FIG. 6A, conductive material 111 is formed on interface layer 220 over substrate 101.

This and any of the narrow-width, widely spaced interconnect lines described above may be integrated into a low-temperature system. A number of structures may be used to lower the system temperature and so allow for the use of narrow interconnect lines. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to integrated circuit packages. In some embodiments, active cooling structures include channels thermally coupled to integrated circuit dies 100. In some embodiments, active cooling structures include channels on one or more sides of integrated circuit dies 100. In some embodiments, active cooling structures include channels within integrated circuit dies 100. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to below 0° C.

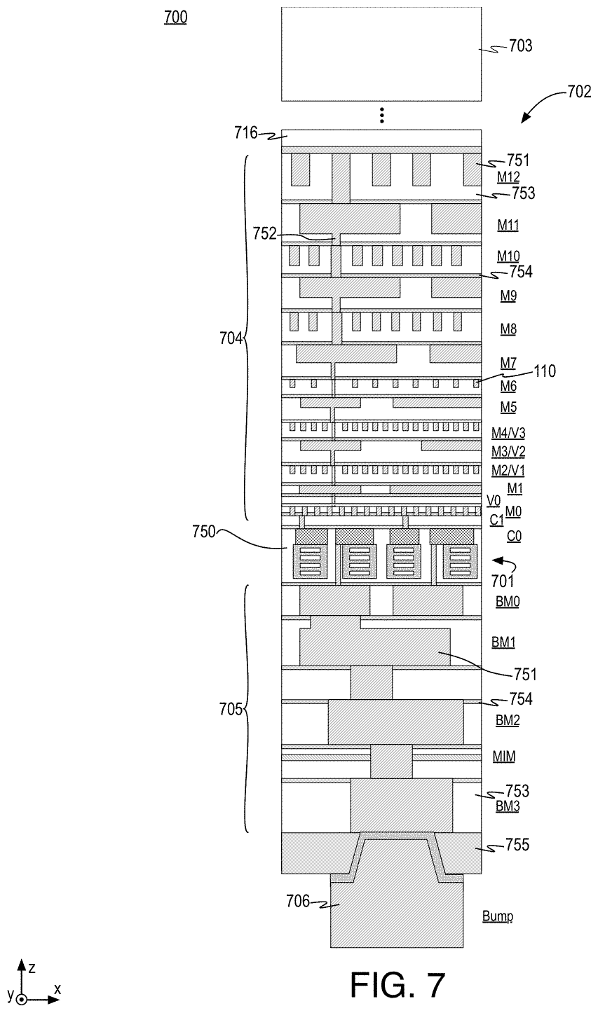

FIG. 7 illustrates a cross-sectional view of a low-temperature, integrated circuit system 700, arranged in accordance with at least some implementations of the present disclosure. Integrated circuit system 700 includes a lateral surface along the x-y plane that may be defined or taken at any vertical position of integrated circuit system 700. The lateral surface of the x-y plane is orthogonal to a vertical or build-up dimension as defined by the z-axis. In some embodiments, integrated circuit system 700 may be formed from any substrate material suitable for the fabrication of transistor circuitry. In some embodiments, a semiconductor substrate is used to manufacture transistors 701 and other components of integrated circuit system 700. The semiconductor substrate may include a wafer or other piece of silicon or another semiconductor material. Suitable semiconductor substrates include, but are not limited to, single crystal silicon, poly crystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 7, integrated circuit system 700 includes an integrated circuit die 702, which is a monolithic integrated circuit including transistors 701, front-side metallization layers 704 (or front-side interconnect layers), and optional back-side metallization layers 705 (or back-side interconnect layers). As shown, transistors 701 are embedded within a dielectric layer 750. In some embodiments, integrated circuit system 700 further includes a package level cooling structure 703, which may be deployed on or over front-side metallization layers 704 (as shown) or on or over a back-side of integrated circuit die 702. In some embodiments, package level cooling structure 703 is coupled to integrated circuit die 702 by an adhesion layer 716. Although illustrated, integrated circuit system 700 may also be deployed without back-side metallization layers 705. In such embodiments, signal routing and power are provided to transistors 701 via front-side metallization layers 704. However, use of back-side metallization layers 705 may offer advantages.

Interconnectivity of transistors 701, signal routing to and from transistors 701, power delivery to transistors 701, and routing to an outside device (not shown), is provided by front-side metallization layers 704, optional back-side metallization layers 705, and package level interconnects 706. In the example of FIG. 7, package level interconnects 706 are provided on or over a back-side of integrated circuit die 702 as bumps over a passivation layer 755. However, package level interconnects 706 may be provided using any suitable interconnect structures such as bond pads, solder bumps, etc. Furthermore, in some embodiments, package level interconnects 706 are provided on or over a front-side of integrated circuit die 702 (i.e., over front-side metallization layers 704) and package level cooling structure 703 is provided on or over a back-side of integrated circuit die 702 (i.e., adjacent transistors 701).

As used herein, the term “metallization layer” describes layers with interconnections or wires that provide electrical routing, including interconnect lines 110 shown in other figures and described above, whether formed of metal or other material, including, e.g., graphene. Adjacent metallization layers may be formed of different materials and by different methods. Interconnect lines 110 and methods to form interconnect lines 110, as discussed herein, can be utilized in one or more of the example layers, including in front-side metallization layers 704 or back-side metallization layers 705. Adjacent metallization layers, such as metallization interconnects 751, are interconnected by vias, such as vias 752, that may be characterized as part of the metallization layers or between the metallization layers. As shown, in some embodiments, front-side metallization layers 704 are formed over and immediately adjacent transistors 701. As used herein, the terms “front-side” and “back-side” are based on the build-up direction of integrated circuit die 702 with the front-side being the side exposed during processing of the substrate used to fabricate transistors 701. The back-side is then the opposite side, which may be exposed during processing by attaching the front-side to a carrier wafer and exposing the back-side (e.g., by back-side grind or etch operations) as known in the art.

As discussed, such very low-temperature operation provides advantages for interconnect lines 110 inclusive of increased conductivity and reduced scattering resistance.

In the illustrated example, front-side metallization layers 704 include M0, V0, M1, M2/V1, M3/V2, M4/V3, and M4-M12. However, front-side metallization layers 704 may include any number of metallization layers such as eight or more metallization layers. Similarly, back-side metallization layers 705 include BM0, BM1, BM2, and BM3. However, back-side metallization layers 705 may include any number of metallization layers such as two to five metallization layers. Front-side metallization layers 704 and back-side metallization layers 705 are embedded within dielectric materials 753, 754. Furthermore, optional metal-insulator-metal (MIM) devices such as diode devices may be provided within back-side metallization layers 705. Other devices such as capacitive memory devices may be provided within front-side metallization layers 704 and/or back-side metallization layers 705.

As discussed, integrated circuit system 700 includes integrated circuit die 702 and an active cooling structure operable to remove heat from integrated circuit die 702 to achieve a very low operating temperature of integrated circuit die 702. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active cooling structure may be provided as a package level structure (i.e., separable from integrated circuit die 702), as a die level structure (i.e., integral to integrated circuit die 702), or both. In some embodiments, an active cooling structure is not needed as integrated circuit die 702 is deployed in a sufficiently cold environment or formed using sufficiently conductive materials.

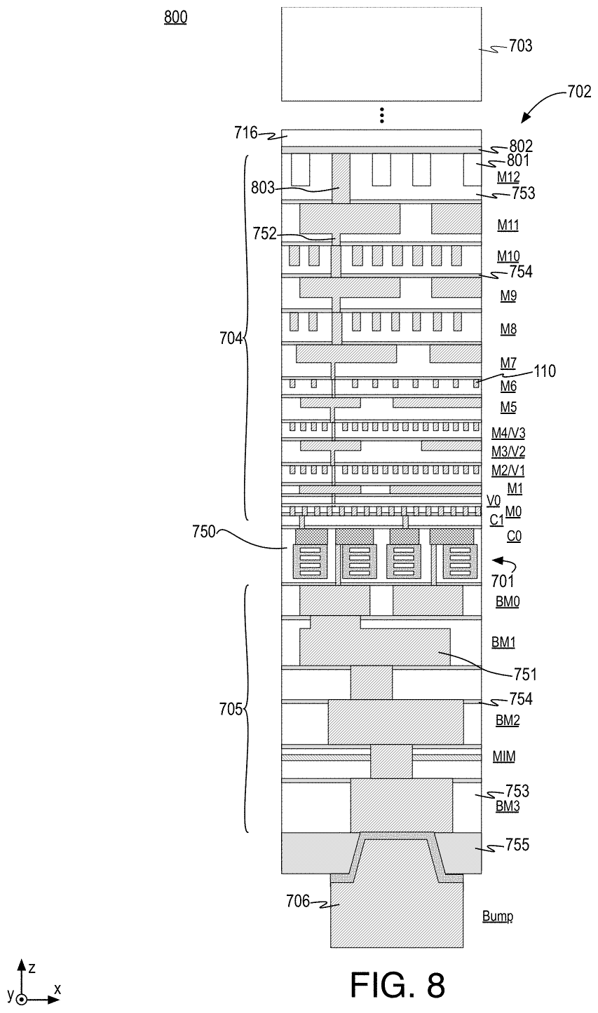

FIG. 8 illustrates a cross-sectional view of a low-temperature integrated circuit system 800 using die-level cooling, arranged in accordance with at least some implementations of the present disclosure. In FIG. 8 and elsewhere herein, like numerals are used to indicate like structures or components that may have any characteristics discussed elsewhere herein. In the example of integrated circuit system 800, integrated circuit die 702 includes active cooling structures or components to remove heat from integrated circuit die 702 to achieve an operating temperature of integrated circuit die 702 at or below a target temperature such as 0° C. or any other operating or target temperature discussed herein.

In integrated circuit system 800, integrated circuit die 702 includes die level active cooling as provided by microchannels 801. Microchannels 801 are to convey a heat transfer fluid therein to remove heat from integrated circuit die 702. The heat transfer fluid may be any suitable liquid or gas. In some embodiments, the heat transfer fluid is liquid nitrogen operable to lower the temperature of integrated circuit die to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such microchannels 801 may be provided in any pattern in the x-y plane such as serpentine patterns, patterns of multiple parallel microchannels 801, or the like. Microchannels 801 couple to a heat exchanger (not shown) that removes heat from and cools the heat transfer fluid before re-introduction to microchannels 801. The flow of fluid within microchannels 801 may be provided by a pump or other fluid flow device. The operation of the heat exchanger, pump, etc. may be controlled by a controller.

In the illustrated embodiment, microchannels 801 are implemented at metallization level M12. In other embodiments, microchannels 801 are implemented over metallization level M12. Microchannels 801 may be formed using any suitable technique or techniques such as patterning and etch techniques to form the void structures of microchannels 801 and passivation or deposition techniques to form a cover structure 802 to enclose the void structures. As shown, in some embodiments, the active cooling structure of integrated circuit system 800 includes a number of microchannels 801 in integrated circuit die 702 and over a number of front-side metallization layers 704. As discussed, microchannels 801 are to convey a heat transfer fluid therein.

In some embodiments, a metallization feature 803 of metallization layer M12 is laterally adjacent to microchannels 801. For example, metallization feature 803 may couple to a package level interconnect structure (not shown) for signal routing for integrated circuit die 702. In the example of integrated circuit system 800, package level cooling structure 703 may be a passive heat removal device such as a heat sink or the like. In some embodiments, package level cooling structure 703 is not deployed in integrated circuit system 800.

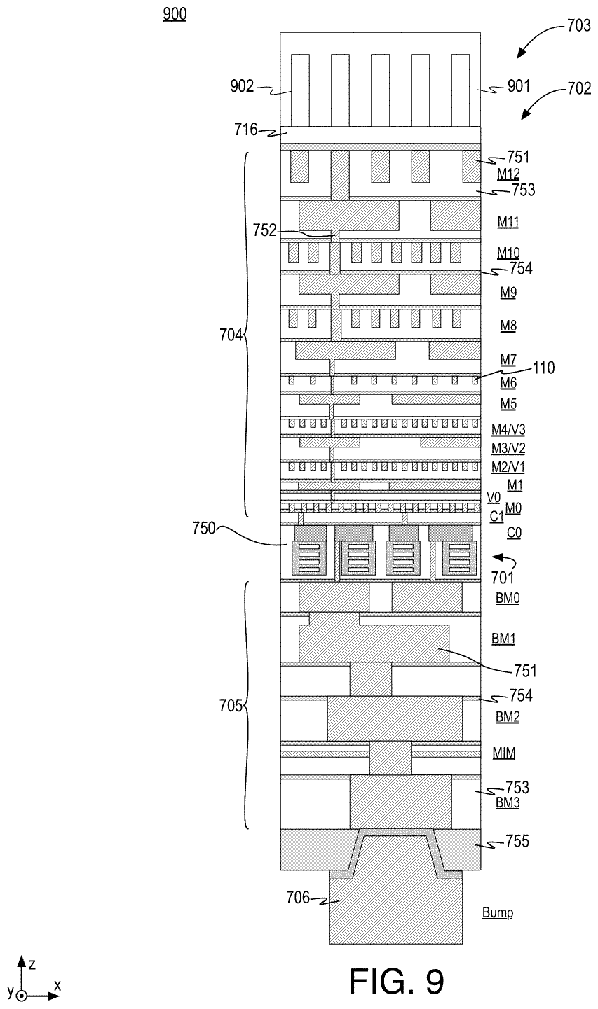

FIG. 9 illustrates a cross-sectional view of a low-temperature integrated circuit system 900 using package-level cooling, arranged in accordance with at least some implementations of the present disclosure. In the example of integrated circuit system 900, integrated circuit die 702 includes active cooling structures or components to remove heat from integrated circuit die 702 to achieve an operating temperature of integrated circuit die 702 at or below a target temperature such as 0° C. or any other operating or target temperature discussed herein.

In integrated circuit system 900, package level cooling structure 703 includes an active cooling structure 901 having microchannels 902. Microchannels 902 are to convey a heat transfer fluid therein to remove heat from integrated circuit die 702. The heat transfer fluid may be any suitable liquid or gas as discussed with respect to FIG. 8. Microchannels 902 may be provided in any pattern in the x-y plane such as serpentine patterns, patterns of multiple parallel microchannels 902, etc. Microchannels 902 couple to a heat exchanger (not shown) that removes heat from and cools the heat transfer fluid before re-introduction to microchannels 902. The flow of fluid within microchannels 902 may be provided by a pump or other fluid-flow device. The operation of the heat exchanger, pump, etc. may be controlled by a controller. In the illustrated embodiment, active cooling structure 901 is a chiller mounted to integrated circuit die 702 such that the chiller has a solid body having microchannels therein to convey a heat transfer fluid.

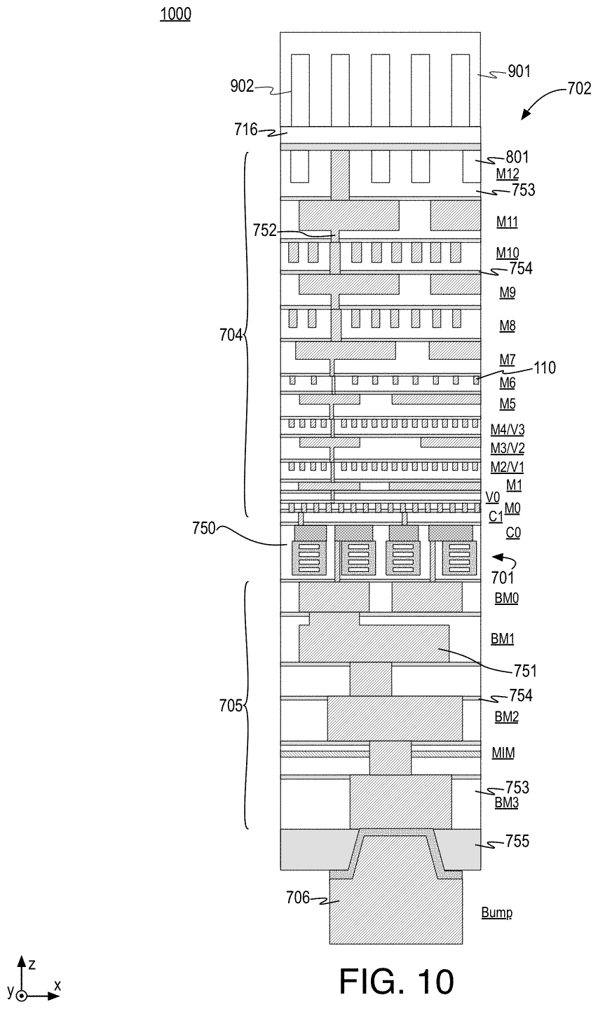

FIG. 10 illustrates a cross-sectional view of a low-temperature integrated circuit system 1000 using die-level and package-level cooling, arranged in accordance with at least some implementations of the present disclosure. In the example of integrated circuit system 1000, integrated circuit die 702 includes active cooling structures or components as provided by both microchannels 801 and active cooling structure 901.

In some embodiments, the heat-removal fluid deployed in microchannels 801 and active cooling structure 901 are coupled to the same pump and heat exchanger systems. In such embodiments, the heat removal fluid conveyed in both microchannels 801 and active cooling structure 901 are the same material. Such embodiments may advantageously provide simplicity. In other embodiments, the heat removal fluids are controlled separately. In such embodiments, the heat removal fluids conveyed by microchannels 801 and active cooling structure 901 may be the same or they may be different. Such embodiments may advantageously provide improved flexibility.

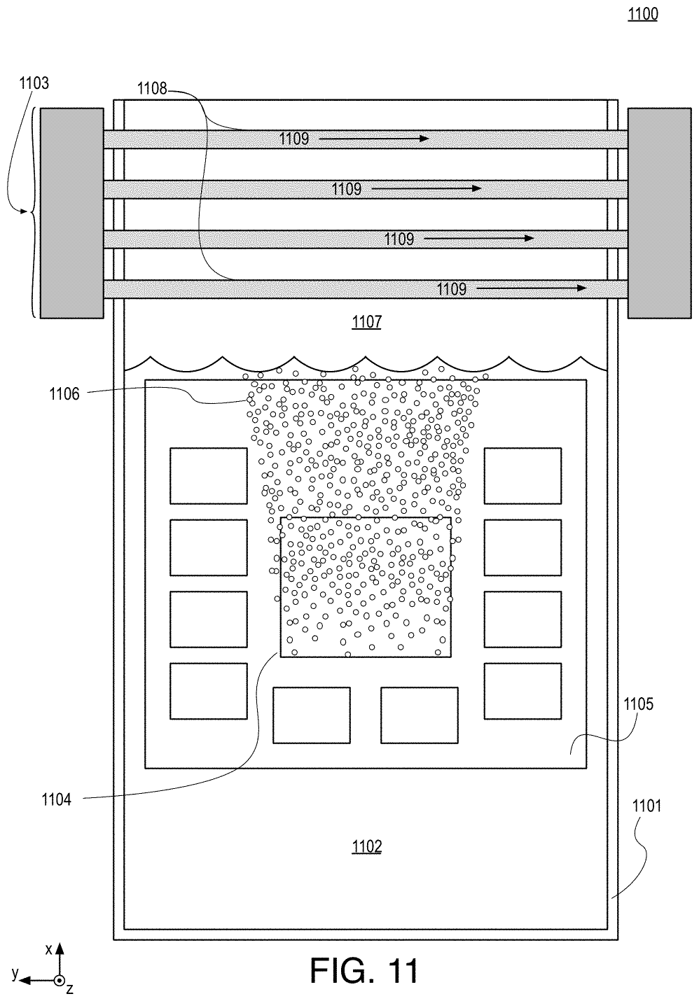

FIG. 11 illustrates a view of an example two-phase immersion cooling system 1100 for low-temperature operation of an integrated circuit die, arranged in accordance with at least some implementations of the present disclosure. As shown, two-phase immersion cooling system 1100 includes a fluid containment structure 1101, a low-boiling point liquid 1102 within fluid containment structure 1101, and a condensation structure 1103 at least partially within fluid containment structure 1101. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 1104, such as an integrated circuit package including any of integrated circuit systems 700, 800 900, 1000 as discussed herein is immersed in low-boiling point liquid 1102. In some embodiments, integrated circuit systems 700, 800 900, 1000 as deployed in two-phase immersion cooling system 1100 do not include additional active cooling structures, although such die level or package level active cooling structures may be used in concert with two-phase immersion cooling system 1100. In some embodiments, when deployed in two-phase immersion cooling system 1100, package level cooling structure 703 is a heat sink, a heat dissipation plate, a porous heat dissipation plate or the like.

Notably, integrated circuit die 702 (or integrated circuit die 100), is the source of heat in the context of two-phase immersion cooling system 1100. For example, integrated circuit die 702 may be packaged and mounted on electronics substrate 1105. Electronic substrate 1105 may be coupled to a power supply (not shown) and may be partially or completely submerged in low-boiling point liquid 1102.

In operation, the heat produced by heat generation source 1104 vaporizes low-boiling point liquid 1102 as shown in vapor or gas state as bubbles 1106, which may collect, due to gravitational forces, above low-boiling point liquid 1102 as a vapor portion 1107 within fluid containment structure 1101. Condensation structure 1103 may extend through vapor portion 1107. In some embodiments, condensation structure 1103 is a heat exchanger having a number of tubes 1108 with a cooling fluid (i.e., a fluid colder than the condensation point of vapor portion 1107) shown by arrows 1109 that may flow through tubes 1108 to condense vapor portion 1107 back to low-boiling point liquid 1102. In the integrated circuit system of FIG. 11, package level cooling structure 703 includes a passive cooling structure such as a heat sink for immersion in low-boiling point liquid 1102.

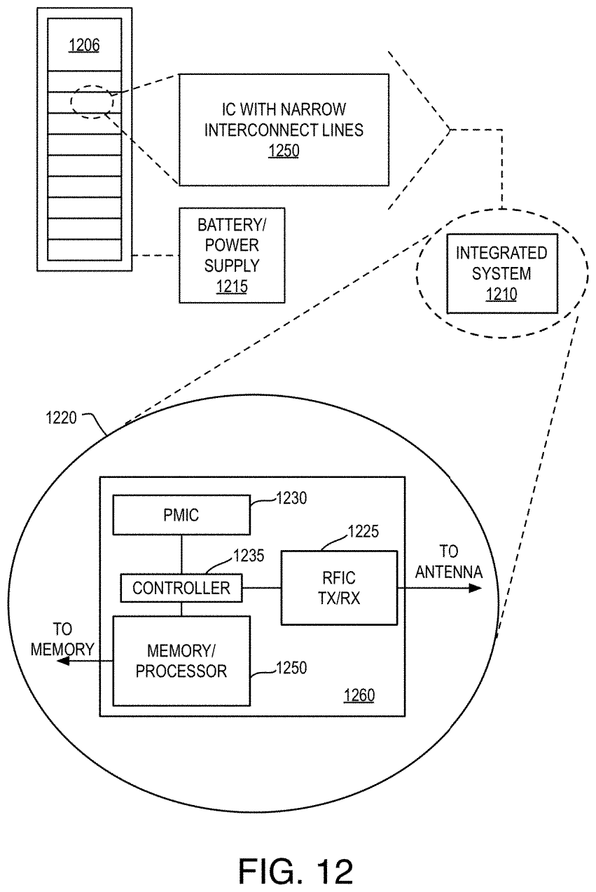

FIG. 12 illustrates a diagram of a data server machine 1206 employing integrated circuit dies with narrow interconnect lines, in accordance with some implementations. Server machine 1206 may be any commercial server, for example, including any number of high-performance computing platforms disposed within a rack and networked together for electronic data processing, which in the exemplary embodiment includes one or more devices 1250 having an integrated circuit with narrow interconnect lines. In some embodiments, example data server machine 1206 has low-temperature active cooling operable to remove heat from the integrated circuit to achieve any low operating temperature discussed herein.

Also as shown, server machine 1206 includes a battery and/or power supply 1215 to provide power to devices 1250, and to provide, in some embodiments, power delivery functions such as power regulation. Devices 1250 may be deployed as part of a package-level integrated system 1210. Integrated system 1210 is further illustrated in the expanded view 1220. In the exemplary embodiment, devices 1250 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1250 is a microprocessor including an SRAM cache memory. As shown, device 1250 may employ a die or device having any interconnect structures and/or related characteristics discussed herein. Device 1250 may be further coupled to (e.g., communicatively coupled to) a board, a substrate, or an interposer 1260 along with, one or more of a power management integrated circuit (PMIC) 1230, RF (wireless) integrated circuit (RFIC) 1225 including a wideband RF (wireless) transmitter and/or receiver (TX/RX) (e.g., including a digital baseband and an analog front end module further includes a power amplifier on a transmit path and a low noise amplifier on a receive path), and a controller 1235 thereof.

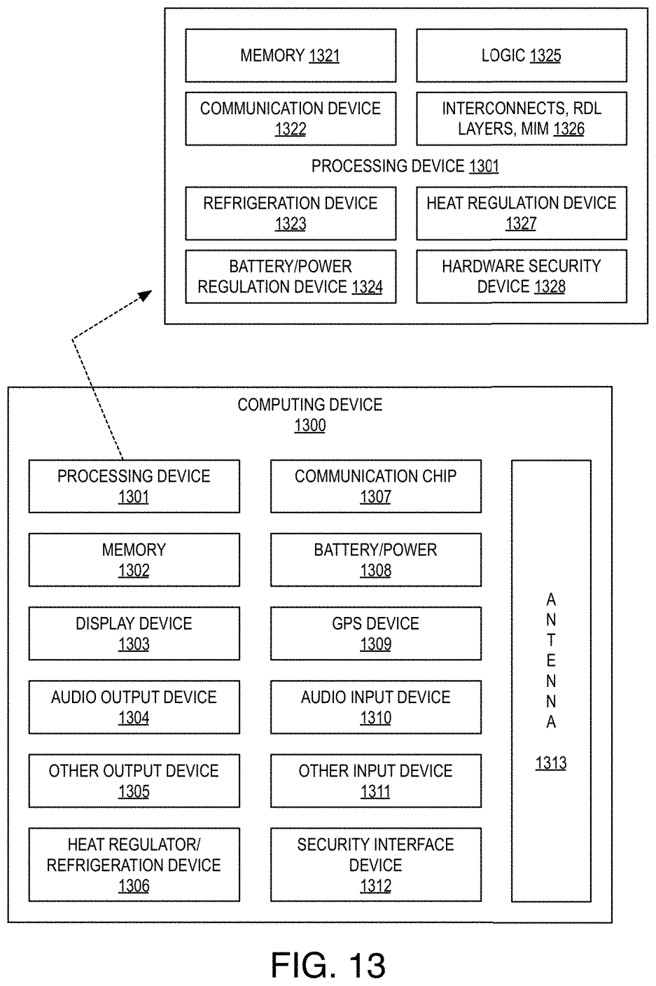

FIG. 13 is a block diagram of a computing device 1300, in accordance with some embodiments of the present disclosure. For example, one or more components of computing device 1300 may include any of the devices or structures discussed herein. A number of components are illustrated in FIG. 13 as being included in computing device 1300, but any one or more of these components may be omitted or duplicated, as suitable for the application. In some embodiments, some or all of the components included in computing device 1300 may be attached to one or more printed circuit boards (e.g., a motherboard). In some embodiments, various ones of these components may be fabricated onto a single system-on-a-chip (SoC) die. Additionally, in various embodiments, computing device 1300 may not include one or more of the components illustrated in FIG. 13, but computing device 1300 may include interface circuitry for coupling to the one or more components. For example, computing device 1300 may not include a display device 1303, but may include display device interface circuitry (e.g., a connector and driver circuitry) to which display device 1303 may be coupled. In another set of examples, computing device 1300 may not include an audio output device 1304, other output device 1305, global positioning system (GPS) device 1309, audio input device 1310, or other input device 1311, but may include audio output device interface circuitry, other output device interface circuitry, GPS device interface circuitry, audio input device interface circuitry, audio input device interface circuitry, to which audio output device 1304, other output device 1305, GPS device 1309, audio input device 1310, or other input device 1311 may be coupled.

Computing device 1300 may include a processing device 1301 (e.g., one or more processing devices). As used herein, the term “processing device” or “processor” indicates a device that processes electronic data from registers and/or memory to transform that electronic data into other electronic data that may be stored in registers and/or memory. Processing device 1301 may include a memory 1321, a communication device 1322, a refrigeration device 1323, a battery/power regulation device 1324, logic 1325, interconnects 1326 (i.e., optionally including redistribution layers (RDL) or metal-insulator-metal (MIM) devices), a heat regulation device 1327, and a hardware security device 1328.

Processing device 1301 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Computing device 1300 may include a memory 1302, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1302 includes memory that shares a die with processing device 1301. This memory may be used as cache memory and may include embedded dynamic random-access memory (eDRAM) or spin transfer torque magnetic random-access memory (STT-M RAM).

Computing device 1300 may include a heat regulation/refrigeration device 1306. Heat regulation/refrigeration device 1306 may maintain processing device 1301 (and/or other components of computing device 1300) at a predetermined low temperature during operation. This predetermined low temperature may be any temperature discussed herein.

In some embodiments, computing device 1300 may include a communication chip 1307 (e.g., one or more communication chips). For example, the communication chip 1307 may be configured for managing wireless communications for the transfer of data to and from computing device 1300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1307 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1307 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1307 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1307 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1307 may operate in accordance with other wireless protocols in other embodiments. Computing device 1300 may include an antenna 1313 to facilitate wireless communications and/or to receive other wireless communications (such as AM or FM radio transmissions).

In some embodiments, communication chip 1307 may manage wired communications, such as electrical, optical, or any other suitable communication protocols (e.g., the Ethernet). As noted above, communication chip 1307 may include multiple communication chips. For instance, a first communication chip 1307 may be dedicated to shorter-range wireless communications such as Wi-Fi or Bluetooth, and a second communication chip 1307 may be dedicated to longer-range wireless communications such as GPS, EDGE, GPRS, CDMA, WiMAX, LTE, EV-DO, or others. In some embodiments, a first communication chip 1307 may be dedicated to wireless communications, and a second communication chip 1307 may be dedicated to wired communications.

Computing device 1300 may include battery/power circuitry 1308. Battery/power circuitry 1308 may include one or more energy storage devices (e.g., batteries or capacitors) and/or circuitry for coupling components of computing device 1300 to an energy source separate from computing device 1300 (e.g., AC line power).

Computing device 1300 may include a display device 1303 (or corresponding interface circuitry, as discussed above). Display device 1303 may include any visual indicators, such as a heads-up display, a computer monitor, a projector, a touchscreen display, a liquid crystal display (LCD), a light-emitting diode display, or a flat panel display, for example.

Computing device 1300 may include an audio output device 1304 (or corresponding interface circuitry, as discussed above). Audio output device 1304 may include any device that generates an audible indicator, such as speakers, headsets, or earbuds, for example.

Computing device 1300 may include an audio input device 1310 (or corresponding interface circuitry, as discussed above). Audio input device 1310 may include any device that generates a signal representative of a sound, such as microphones, microphone arrays, or digital instruments (e.g., instruments having a musical instrument digital interface (MIDI) output).

Computing device 1300 may include a GPS device 1309 (or corresponding interface circuitry, as discussed above). GPS device 1309 may be in communication with a satellite-based system and may receive a location of computing device 1300, as known in the art.

Computing device 1300 may include other output device 1305 (or corresponding interface circuitry, as discussed above). Examples of the other output device 1305 may include an audio codec, a video codec, a printer, a wired or wireless transmitter for providing information to other devices, or an additional storage device.

Computing device 1300 may include other input device 1311 (or corresponding interface circuitry, as discussed above). Examples of the other input device 1311 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1300 may include a security interface device 1312. Security interface device 1312 may include any device that provides security measures for computing device 1300 such as intrusion detection, biometric validation, security encode or decode, access list management, malware detection, or spyware detection,

Computing device 1300, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

It is understood that the subject matter of the present description is not necessarily limited to specific applications illustrated in FIGS. 1-13. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an integrated circuit (IC) die comprises a plurality of transistors, and an interconnect layer above the transistors, the interconnect layer comprising a plurality of substantially parallel interconnect lines, the substantially parallel interconnect lines having a pitch of not more than 75 nm and a line-space duty cycle of less than 50%.

In one or more second embodiments, further to the first embodiments, the line-space duty cycle of the interconnect lines is not more than 30%.

In one or more third embodiments, further to the first or second embodiments, the line-space duty cycle of the interconnect lines is not more than 1%.

In one or more fourth embodiments, further to the first through third embodiments, the interconnect lines comprise graphene.

In one or more fifth embodiments, further to the first through fourth embodiments, the interconnect lines comprise metal and at least one of sulfur, selenium, or tellurium.

In one or more sixth embodiments, further to the first through fifth embodiments, the metal comprises copper.

In one or more seventh embodiments, further to the first through sixth embodiments, the interconnect lines comprise at least one of ruthenium or tungsten.

In one or more eighth embodiments, further to the first through seventh embodiments, a first of the interconnect lines has a bottom width proximal the transistors greater than a top width distal from the transistors.

In one or more ninth embodiments, further to the first through eighth embodiments, an adjacent pair of the interconnect lines have inner sidewall heights greater than outer sidewall heights.

In one or more tenth embodiments, further to the first through ninth embodiments, one or more of the interconnect lines is on an adhesive layer above a dielectric layer.

In one or more eleventh embodiments, further to the first through tenth embodiments, the adhesive layer comprises titanium or tantalum.

In one or more twelfth embodiments, further to the first through eleventh embodiments, a cooling structure is operable to remove heat from the IC die to achieve an operating temperature at or below −25° C.

In one or more thirteenth embodiments, a system comprises an integrated circuit (IC) die comprising a plurality of transistors below a plurality of interconnect lines on one or more dielectric layers, wherein the transistors are electrically connected to the interconnect lines, and wherein a line-space duty cycle of the interconnect lines is not more than 50%, a cooling structure thermally coupled to the IC die, the cooling operable to remove heat from an IC die to achieve an operating temperature at or below −25° C., and a power supply electrically coupled to the IC die.

In one or more fourteenth embodiments, further to the thirteenth embodiments, the cooling structure comprises a plurality of microchannels in the IC die and over the interconnect lines, the microchannels to convey a heat transfer fluid therein.

In one or more fifteenth embodiments, further to the thirteenth or fourteenth embodiments, a first of the interconnect lines has a bottom width proximal the transistors greater than a top width distal from the transistors.

In one or more sixteenth embodiments, further to the thirteenth through fifteenth embodiments, the line-space duty cycle of the interconnect lines is not more than 30%.

In one or more seventeenth embodiments, a method comprises receiving an integrated circuit (IC) die comprising a plurality of transistors and a dielectric layer above the transistors, forming a plurality of interconnect lines on an upper surface of the dielectric layer, wherein the interconnect lines are electrically connected to the transistors and a line-space duty cycle of the interconnect lines is not more than 50%, and removing portions of the interconnect lines.

In one or more eighteenth embodiments, further to the seventeenth embodiments, the line-space duty cycle of the interconnect lines is not more than 30%.

In one or more nineteenth embodiments, further to the seventeenth or eighteenth embodiments, the line-space duty cycle of the interconnect lines is not more than 1%.

In one or more twentieth embodiments, further to the seventeenth through nineteenth embodiments, the removing portions of the interconnect lines comprises polishing the interconnect lines and the upper surface of the dielectric layer.

In one or more twenty-first embodiments, further to the seventeenth through twentieth embodiments, the forming a plurality of interconnect lines comprises forming nonconductive features on the upper surface of the dielectric layer and forming one or more layers of a conductive material over the nonconductive features.

In one or more twenty-second embodiments, further to the seventeenth through twenty-first embodiments, the forming the plurality of interconnect lines comprises forming an adhesive layer on the nonconductive features and the forming one or more layers of the conductive material over the nonconductive features comprises forming the one or more layers of the conductive material on the adhesive layer.

In one or more twenty-third embodiments, further to the seventeenth through twenty-second embodiments, the removing portions of the interconnect lines comprises polishing the interconnect lines and the upper surface of the dielectric layer.

In one or more twenty-fourth embodiments, further to the seventeenth through twenty-third embodiments, the removing portions of the interconnect lines comprises etching to form one or more discontinuities in all of the one or more layers of the conductive material.

It will be recognized that the disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) die, comprising:
a plurality of transistors; and
an interconnect layer above the transistors, the interconnect layer comprising a plurality of substantially parallel interconnect lines, the substantially parallel interconnect lines having a pitch of not more than 75 nm and a line-space duty cycle of less than 50%.

2. The IC die of claim 1, wherein the line-space duty cycle of the interconnect lines is not more than 30%.

3. The IC die of claim 2, wherein the line-space duty cycle of the interconnect lines is not more than 1%.

4. The IC die of claim 1, wherein the interconnect lines comprise graphene.

5. The IC die of claim 1, wherein the interconnect lines comprise metal and at least one of sulfur, selenium, or tellurium.

6. The IC die of claim 5, wherein the metal comprises copper.

7. The IC die of claim 1, wherein the interconnect lines comprise at least one of ruthenium or tungsten.

8. The IC die of claim 1, wherein a first of the interconnect lines has a bottom width proximal the transistors greater than a top width distal from the transistors.

9. The IC die of claim 1, wherein an adjacent pair of the interconnect lines have inner sidewall heights greater than outer sidewall heights.

10. The IC die of claim 1, wherein one or more of the interconnect lines is on an interface layer above a dielectric layer.

11. The IC die of claim 10, wherein the interface layer comprises titanium or tantalum.

12. The IC die of claim 1, further comprising a cooling structure operable to remove heat from the IC die to achieve an operating temperature at or below −25° C.

13. A system, comprising:
an integrated circuit (IC) die comprising a plurality of transistors below a plurality of interconnect lines on one or more dielectric layers, wherein the transistors are electrically connected to the interconnect lines, and wherein a line-space duty cycle of the interconnect lines is not more than 50%;
a cooling structure thermally coupled to the IC die, the cooling operable to remove heat from an IC die to achieve an operating temperature at or below −25° C.; and
a power supply electrically coupled to the IC die.

14. The system of claim 13, wherein the cooling structure comprises a plurality of microchannels in the IC die and over the interconnect lines, the microchannels to convey a heat transfer fluid therein.

15. The system of claim 13, wherein a first of the interconnect lines has a bottom width proximal the transistors greater than a top width distal from the transistors.

16. The system of claim 13, wherein the line-space duty cycle of the interconnect lines is not more than 30%.

17. A method, comprising:
receiving an integrated circuit (IC) die comprising a plurality of transistors and a dielectric layer above the transistors;
forming a plurality of interconnect lines on an upper surface of the dielectric layer, wherein the interconnect lines are electrically connected to the transistors; and
removing portions of the interconnect lines, wherein a line-space duty cycle of the interconnect lines is not more than 50%.

18. The method of claim 17, wherein the line-space duty cycle of the interconnect lines is not more than 30%.

19. The method of claim 18, wherein the line-space duty cycle of the interconnect lines is not more than 1%.

20. The method of claim 17, wherein the removing portions of the interconnect lines comprises polishing the interconnect lines and the upper surface of the dielectric layer.

21. The method of claim 17, wherein the forming a plurality of interconnect lines comprises forming nonconductive features on the upper surface of the dielectric layer and forming one or more layers of a conductive material over the nonconductive features.

22. The method of claim 21, wherein the forming the plurality of interconnect lines comprises forming an interface layer on the nonconductive features and the forming one or more layers of the conductive material over the nonconductive features comprises forming the one or more layers of the conductive material on the interface layer.

23. The method of claim 21, wherein the removing portions of the interconnect lines comprises polishing the interconnect lines and the upper surface of the dielectric layer.

24. The method of claim 21, wherein the removing portions of the interconnect lines comprises etching to form one or more discontinuities in all of the one or more layers of the conductive material.
